(19) United States
(12) Patent Application Publication
(10) Pub. No.: US 2020/0243449 A1
(43) Pub. Date: Jul. 30, 2020

(54) PACKAGE STRUCTURE AND MANUFACTURING METHOD THEREOF

(71) Applicant: Powertech Technology Inc., Hsinchu County (TW)

(72) Inventors: Chia-Wei Chiang, Hsinchu County (TW); Li-Chih Fang, Hsinchu County (TW); Wen-Jeng Fan, Hsinchu County (TW)

(73) Assignee: Powertech Technology Inc., Hsinchu County (TW)

(21) Appl. No.: 16/261,566

(22) Filed: Jan. 30, 2019

(51) Int. Cl. H01L 23/538; H01L 23/31; H01L 23/00; H01L 25/10; H01L 21/48; H01L 21/56; H01L 25/00

(52) U.S. Cl. CPC H01L 23/5381; H01L 2224/214; H01L 23/5383; H01L 23/5386; H01L 23/5389; H01L 24/20; H01L 25/105; H01L 21/4857; H01L 21/4853; H01L 21/568; H01L 21/565; H01L 24/19; H01L 25/50; H01L 2225/1035; H01L 2225/1058; H01L 23/3128

(57) ABSTRACT

A package structure includes a redistribution structure, a bridge die, a plurality of conductive pillars, at least two dies, and an insulating encapsulant. The bridge die provides an electrical connection between the at least two dies. The conductive pillars provide an electrical connection between the at least two dies and the redistribution structure. The insulating encapsulant is disposed on the redistribution structure, encapsulates the bridge die and the conductive pillars, and covers each of the at least two dies. The bridge die of the package structure may be used to route signals between the at least two dies, allowing for a higher density of interconnecting routes between the at least two dies.

### BACKGROUND OF THE INVENTION

### Field of the Invention

The disclosure generally relates to a package structure and a manufacturing method thereof, and in particular, to a package structure having a bridge die and a manufacturing method thereof.

### Description of Related Art

In the development of semiconductor package technology, a focus is to produce package structures with higher densities of components and interconnects, and ever higher performances, while maintaining or increasing a high reliability and durability at a lower manufacturing cost. One strategy is to employ bridge dies as interconnects for other dies within the package structure. One of the challenges lies in how to connect the bridge die with the other dies, such that a high broadband transfer of signals may be achieved between the dies in a reliable, durable and cost-effective package structure.

### SUMMARY OF THE INVENTION

The disclosure provides a package structure and a manufacturing method thereof, which provides for a higher density of interconnecting routes between dies therein in a reliable, durable package structure that can be manufactured at a lower cost.

The disclosure provides a package structure including a redistribution structure, a bridge die, a plurality of conductive pillars, at least two dies, and an insulating encapsulant. The bridge die is disposed on the redistribution structure. The conductive pillars are disposed at a periphery of the bridge die and on the redistribution structure, and are electrically connected to the redistribution structure. The at least two dies are disposed on the bridge die and the conductive pillars opposite to the redistribution structure. Each of the at least two dies has an active surface and a lateral surface connected to the active surface and includes a plurality of conductive pads disposed on the active surface and electrically connected to the bridge die and the conductive pillars. The insulating encapsulant is disposed on the redistribution structure, encapsulates the bridge die and the conductive pillars, and covers the active surface and the lateral surface of each of the at least two dies.

The disclosure provides a manufacturing method of a package structure. The method includes at least the following steps. A carrier is provided. At least two dies are disposed on the carrier. Each of the at least two dies has an active surface and a rear surface opposite the active surface and includes a plurality of conductive pads disposed on the active surface. The rear surface faces the carrier. A bridge die is disposed and a plurality of conductive pillars is formed on the at least two dies opposite to the carrier. The bridge die has an active surface and a rear surface opposite the active surface of the bridge die. The bridge die is electrically connected to each of the at least two dies through the active surface of the bridge die. The conductive pillars are electrically connected to each of the at least two dies. An insulating encapsulant is formed to encapsulate the at least two dies, the bridge die and the conductive pillars. A redistribution structure is formed on the insulating encapsulant opposite to the carrier. The redistribution structure is electrically connected to the conductive pillars. The carrier is removed from the insulating encapsulant and the at least two dies.

Based on the above, the bridge die of the package structure may be used to route signals between the at least two dies, allowing for a higher density of interconnecting routes between the at least two dies. The higher density of interconnecting routes allows for a high bandwidth transfer of signals between the at least two dies. The high bandwidth allows for faster communication between, for example, processor and memory dies, and thereby a faster operation of the package structure. The insulating encapsulant provides additional mechanical support to the electrical connection from the redistribution structure to the at least two dies, that is the conductive pillars electrically connecting the at least two dies to the redistribution structure. The additional mechanical support increases a reliability and durability of the package structure at a lower manufacturing cost.

To make the aforementioned more comprehensible, several embodiments accompanied with drawings are described in detail as follows.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles presented in the disclosure. Identical or similar numbers refer to identical or similar elements throughout the drawings.

FIG. 1A to FIG. 1H are schematic cross-sectional views illustrating a manufacturing method of a package structure according to an embodiment of the disclosure.

FIG. 2 is a schematic cross-sectional view of an intermediate step in a manufacturing method of a package structure according to an embodiment of the disclosure.

FIG. 3A to FIG. 3C are schematic cross-sectional views illustrating a manufacturing method of a package structure according to another embodiment of the disclosure.

FIG. 4 is a schematic cross-sectional view illustrating an application of a package structure according to an embodiment of the disclosure.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

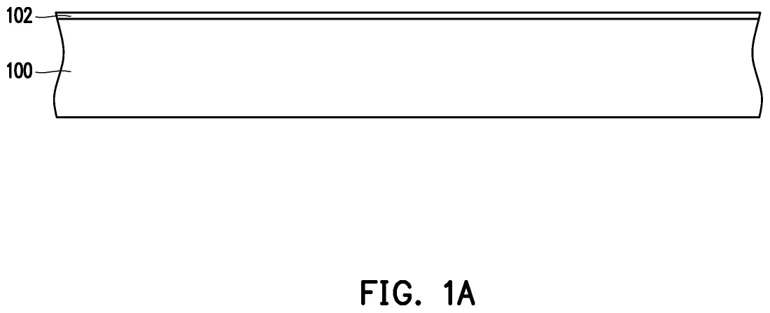

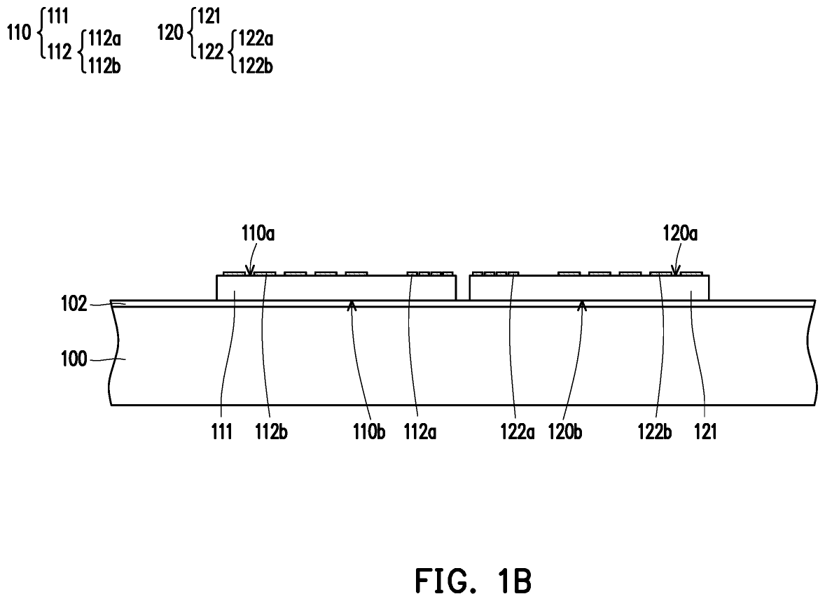

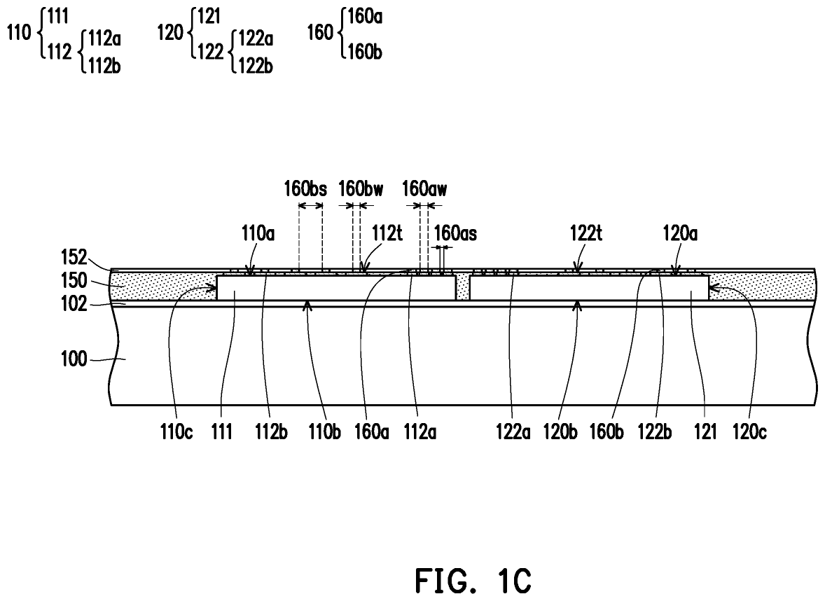

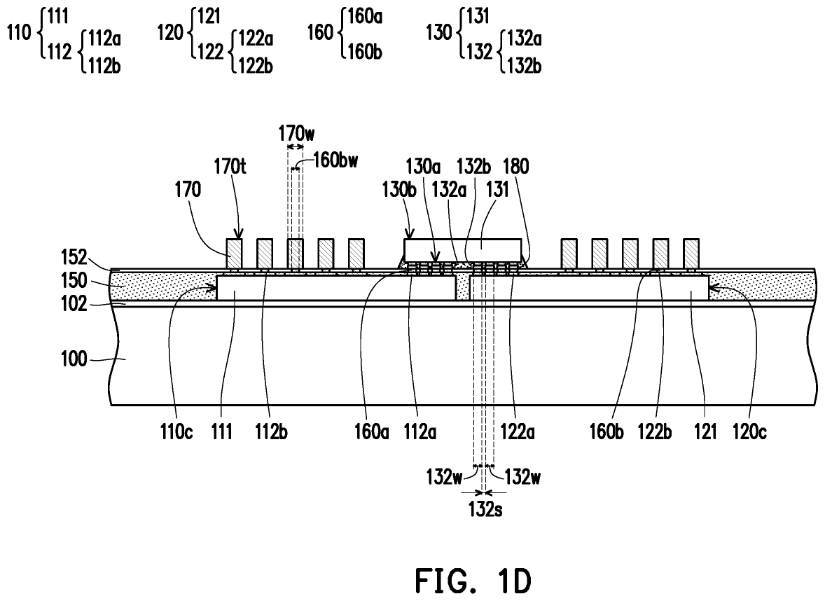

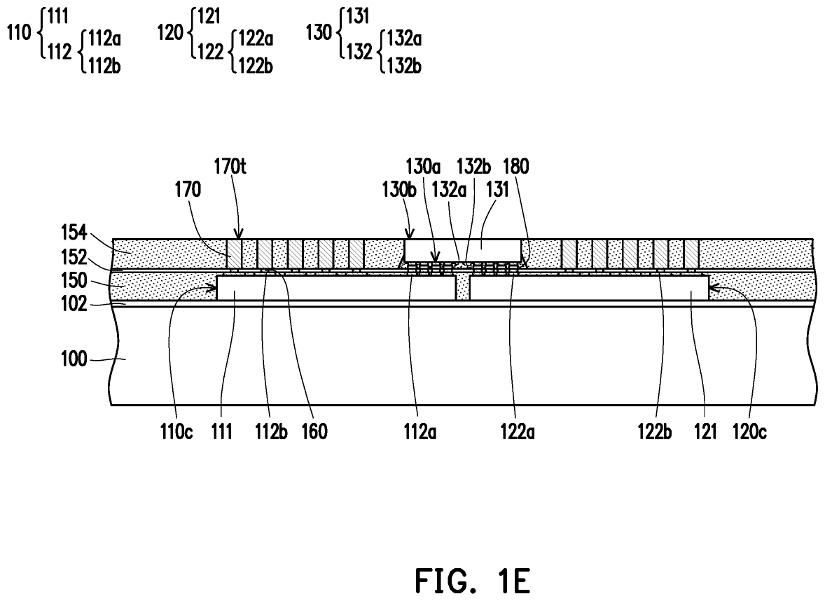

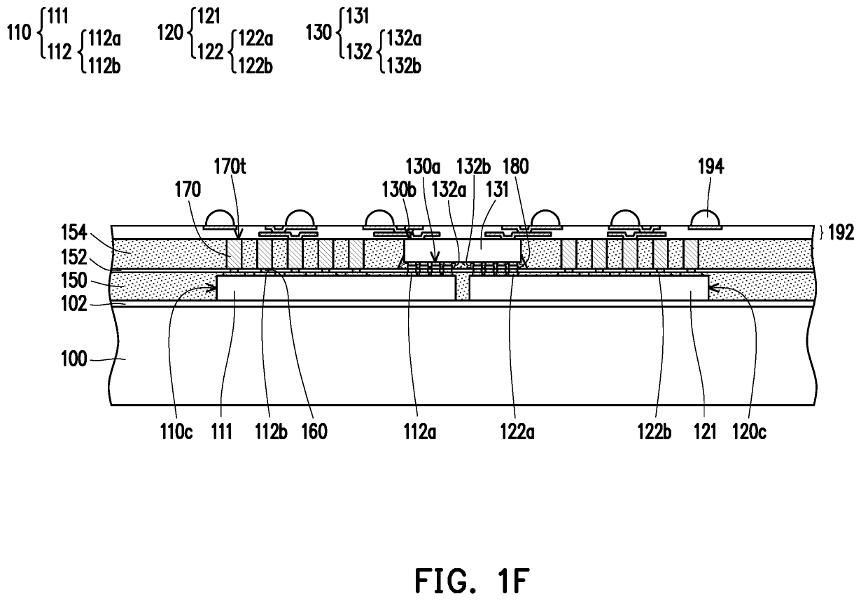

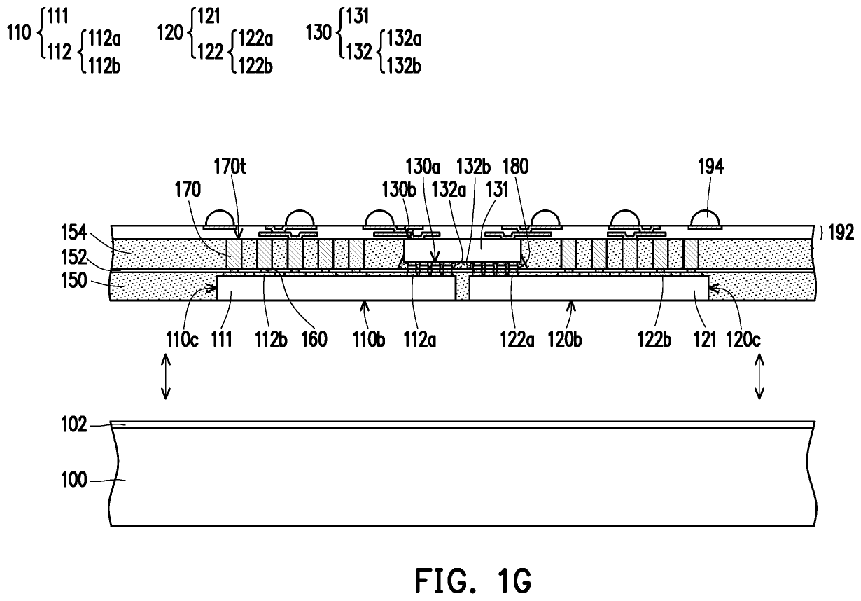

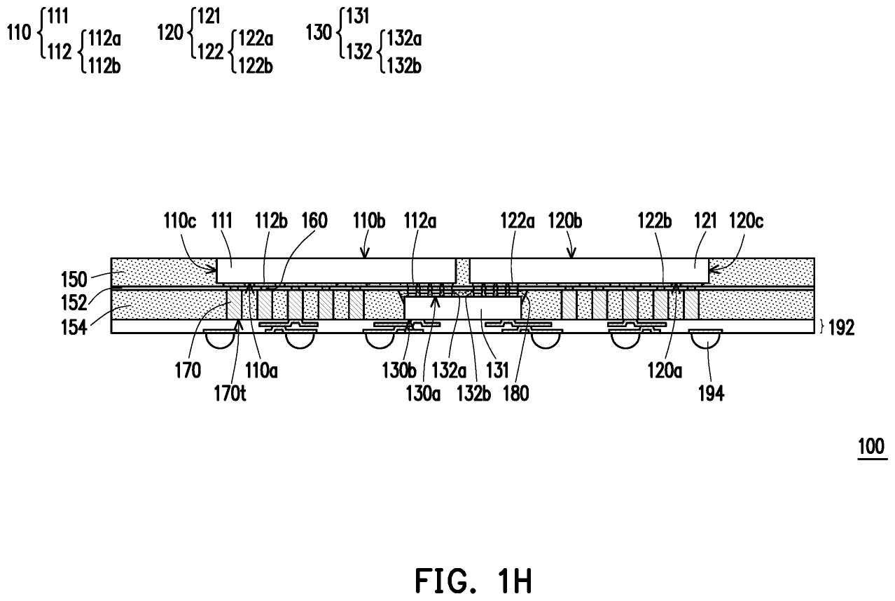

FIG. 1A to FIG. 1H are schematic cross-sectional views illustrating a manufacturing method of a package structure according to an embodiment of the disclosure. Referring to FIG. 1A, a carrier 100 having a debonding layer 102 formed thereon is provided. The carrier 100 may be a glass substrate or a glass supporting board. However, the present disclosure is not limited thereto. Other suitable substrate materials may be used as long as the materials are able to withstand subsequent processes while structurally supporting the package structure formed thereon. The debonding layer 102 may include light to heat conversion (LTHC) materials, epoxy resins, inorganic materials, organic polymeric materials, or other suitable adhesive materials. However, the present disclosure is not limited thereto, as other suitable debonding layers may be used in alternative embodiments. In some embodiments, layers of the package structure, such as the carrier 100, the debonding layer 102 and layers disposed or formed thereon, extend horizontally in two dimensions along both directions in each of a length and a width beyond an area required for one package structure, such that a plurality of package structures may be simultaneously formed by using a wafer-level packaging process and a singulation process.

Referring to FIG. 1B, at least two dies are disposed on a surface of the carrier 100 having the debonding layer 102. In some embodiments, the at least two dies may comprise of a first die 110 and a second die 120, as shown in FIGS. 1A-1H and as described in the exemplary embodiments presented herein. However, the present disclosure is not limited thereto, as the at least two dies may number three or more dies. The at least two dies may include digital dies, analog dies, or mixed signal dies. For example, the at least two dies may be application-specific integrated circuit (ASIC) dies, logic dies, other suitable dies or a combination thereof. Dies of the at least two dies may have different functions. For example, the first die 110 may be a processor die and the second die 120 may be a memory die. However, the present disclosure is not limited thereto, some or all of the at least two dies may have a same function. Each of the at least two dies has an active surface and a rear surface opposite to the active surface. For instance, the first die 110 has an active surface 110a and a rear surface 110b opposite the active surface 110a, and the second die 120 has an active surface 120a and a rear surface 120b opposite the active surface 120a. The first die 110 and the second die 120 are disposed on the carrier 100, such that the rear surface 110b of the first die 110 and the rear surface 120b of the second die 120 face the carrier 100.

Each of the at least two dies includes a semiconductor substrate and a plurality of conductive pads. The conductive pads include a plurality of first conductive pads and a plurality of second conductive pads. The first die 110 may include a semiconductor substrate 111 and a plurality of conductive pads 112. The second die 120 may include a semiconductor substrate 121 and a plurality of conductive pads 122. The conductive pads 112 include a plurality of first conductive pads 112a and a plurality of second conductive pads 112b. The conductive pads 122 include a plurality of first conductive pads 122a and a plurality of second conductive pads 122b.

In some embodiments, the semiconductor substrate 111 and the semiconductor substrate 121 may be a silicon substrate including active components (e.g., transistors or the like) and, optionally, passive components (e.g., resistors, capacitors, inductors, or the like) formed therein. The conductive pads 112 are distributed on the semiconductor substrate 111 on the active surface 110a. The conductive pads 122 are distributed on the semiconductor substrate 121 on the active surface 120a. The conductive pads 112 and 122 may include aluminum pads, copper pads, or other suitable metal pads.

Referring to FIG. 1C, an insulating material is formed on the carrier 100 to encapsulate the first die 110 and the second die 120. A thickness of the insulating material is reduced to expose top surfaces of the conductive pads of each of the at least two dies. For instance, a thickness of the insulating material is reduced to form a first insulating encapsulant 150. The first insulating encapsulant 150 may expose top surfaces 112t of the conductive pads 112 and top surfaces 122t of the conductive pads 122. The first insulating encapsulant 150 covers at least a portion of the active surface 110a and a lateral surface 110c of the first die 110, and at least a portion of the active surface 120a and a lateral surface 120c of the second die 120. The lateral surface 110c is configured to connect the active surface 110a and the rear surface 110b. The lateral surface 120c is configured to connect the active surface 120a and the rear surface 120b. In some embodiments, the top surfaces 112t and the top surfaces 122t are substantially coplanar to each other. The insulating material may include a molding compound formed by a molding process or an insulating material such as epoxy, silicone, or other suitable resins. In some embodiments, the insulating material may be removed through a planarization process. The planarization process may include chemical mechanical polishing (CMP), mechanical grinding, etching, or other suitable process.

After forming the first insulating encapsulant 150, a passivation layer 152 may be formed on the first insulating encapsulant 150 and the at least two dies. The passivation layer 152 may be a silicon oxide layer, a silicon nitride layer, a silicon oxy-nitride layer, or a dielectric layer formed of polymeric materials or other suitable dielectric materials. A plurality of openings is formed in the passivation layer 152 to expose at least a portion of each of the conductive pads of each of the at least two dies. FIG. 1C shows straight openings in the passivation layer 152, but the present disclosure is not limited thereto. For instance, some or all of the openings may be tapered. The tapered openings may, for example, be tapered toward the conductive pads. A plurality of conductive vias 160 may be formed to fill the openings of the passivation layer 152. The plurality of conductive vias 160 includes a plurality of first conductive vias 160a and a plurality of second conductive vias 160b. Each of the first conductive vias 160a may have a width 160aw less than or equal to a width 160bw of each of the second conductive vias 160b. A spacing 160as of the first conductive vias 160a may be shorter than a spacing 160bs of the second conductive vias 160b, but the present disclosure is not limited thereto. The conductive vias 160 may be formed by sputtering, evaporation, electroless plating, electroplating, immersion plating, or the like. The conductive vias 160 may be made of copper, aluminum, nickel, gold, silver, tin, a combination thereof, a composite structure of copper/nickel/gold, or other suitable conductive materials.

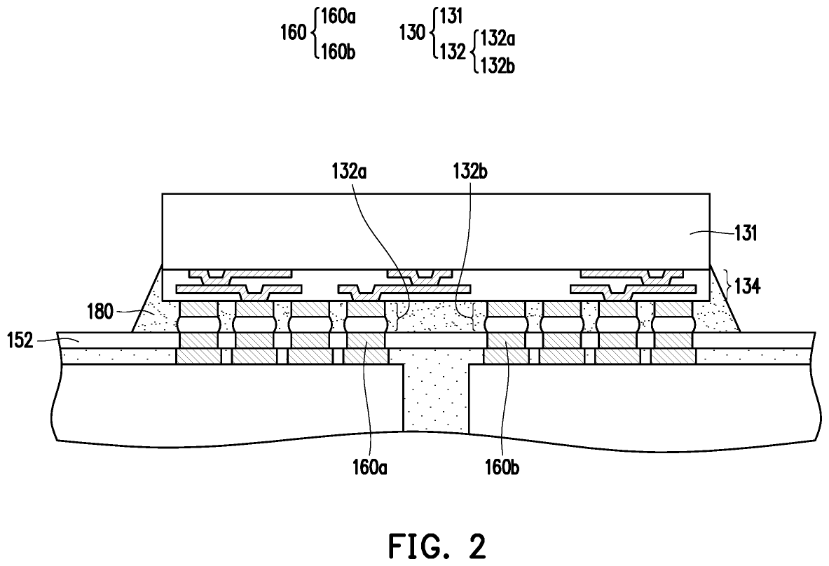

Referring to FIG. 1D, a bridge die 130 and a plurality of conductive pillars 170 are correspondingly disposed and formed on the passivation layer 152. The bridge die 130 has an active surface 130a and a rear surface 130b opposite to the active surface 130a. The bridge die 130 includes a semiconductor substrate 131. In some embodiments, the semiconductor substrate 131 may be a silicon substrate. The bridge die 130 may further include a plurality of conductive bumps 132 and, optionally, a redistribution layer to interconnect the plurality of conductive bumps 132, which is shown as the redistribution layer 134 in FIG. 2. The plurality of conductive bumps 132 includes a plurality of conductive bumps for each of the at least two dies. For instance, the plurality of conductive bumps 132 includes a plurality of first conductive bumps 132a to electrically connect to the first die 110 and a plurality of second conductive bumps 132b to electrically connect to the second die 120. The conductive bumps 132 are distributed on the semiconductor substrate 131 on the active surface 130a. The conductive bumps 132 may include pillar bumps, C2 (chip connection) bumps or C4 (controlled collapse chip connection) bumps, and may include copper, nickel, tin, silver, a combination thereof or the like. A width 132w of the conductive bumps 132, a spacing 132s of the first conductive bumps 132a and a spacing 132s of the second conductive bumps 132b are less than 2 micrometers.

As illustrated in FIG. 1D, the bridge die 130 is disposed in a face down manner such that the active surface 130a faces the first die 110 and the second die 120. The bridge die 130 may be electrically connected to the first die 110 and the second die 120 through flip-chip bonding. For instance, the first conductive bumps 132a and the second conductive bumps 132b may be disposed on the passivation layer, wherein each of the conductive bumps 132a and 132b is directly in contact with the first conductive vias 160a above the first die 110 and the second die 120 respectively. As such, the first die 110 and the second die 120 may both be electrically connected to the bridge die 130, and the bridge die 130 may be used to route electrical signals between the first die 110 and the second die 120.

The bridge die 130 may be a passive die, wherein the semiconductor substrate 131 includes conductive traces and optionally passive components (e.g., resistors, capacitors, inductors, or the like) formed therein such that electrical signals may be transmitted between the first die 110 and the second die 120. Alternatively, the bridge die 130 may be an active die, wherein the semiconductor substrate 131 includes active components (e.g., transistors or the like) in addition to the conductive traces and optionally the passive components. The bridge die 131 may be a digital die, analog die, or mixed signal die. For example, the bridge die may be an application-specific integrated circuit (ASIC) die, logic die, or other suitable die.

In some embodiments, an underfill 180 is formed between the passivation layer 152 and the bridge die 130 to protect and isolate the electrical connection between the conductive bumps 132 and the first conductive vias 160a. The underfill 180 may be formed by a capillary underfill (CUF) process and may include polymeric materials, resins, or silica additives.

The conductive pillars 170 may be formed on the passivation layer 152, wherein each conductive pillars 170 is directly in contact with one of the second conductive vias 160b. The conductive pillars 170 may be formed using lithography, plating, photoresist stripping, or any other suitable processes. The conductive pillars 170 may be made of copper, aluminum, nickel, gold, a combination thereof, or other suitable conductive materials. The conductive pillars 170 may be formed by forming a mask (not shown) having openings, where the openings expose a portion of the passivation layer 152; disposing a conductive material to fill the openings of the mask by plating or deposition; and removing the mask to form the conductive pillars 170. The conductive pillars 170 may be formed such that top surfaces 170t of the conductive pillars 170 and the rear surface 130b of the bridge die 130 are colinear. However, the present disclosure is not limited thereto, for instance, the conductive pillars 170 may be formed such that the top surfaces 170t are higher than the rear surface 130b of the bridge die 130. A width 170w of each of the conductive pillars 170 may be greater than a width 160bw of the second conductive vias 160b, but the present disclosure is not limited thereto.

Referring to FIG. 1E, an insulating material is formed on the passivation layer 152 to encapsulate the bridge die 130, the underfill 180 and the conductive pillars 170. A thickness of the insulating material is reduced to expose the top surfaces 170t of the conductive pillars 170 and the rear surface 130b of the bridge die 130, thereby forming a second insulating encapsulant 154. In some embodiments, the top surfaces 170t and the rear surface 130b are substantially coplanar to each other. In embodiments where the top surfaces 170t of the conductive pillars 170 are higher than the rear surface of the bridge die 130, the insulating material is reduced to expose the top surfaces 170t. The second insulating encapsulant 154 may be formed and made of a material as described for the first insulating encapsulant 150. The material of the second insulating encapsulant 154 may be the same as or different from that of the first insulating encapsulant 150. In some embodiments, after the top surfaces 170t of the conductive pillars 170 and the rear surface 130b of the bridge die 130 are exposed, the conductive pillars 170, the bridge die 130 and second insulating encapsulant 154 may be further grinded to reduce the overall thickness of the subsequently formed package structure 100.

Referring to FIG. 1F, a redistribution structure 192 is formed on the second insulating encapsulant 154. The redistribution structure 192 may include at least one dielectric layer and a plurality of conductive traces. The dielectric layers may be formed by suitable fabrication techniques such as spin-on coating, chemical vapor deposition (CVD), plasma-enhanced chemical vapor deposition (PECVD), or the like. The dielectric layers may be made of non-organic or organic dielectric materials such as silicon oxide, silicon nitride, silicon carbide, silicon oxynitride, polyimide, benzocyclobutene (BCB), or the like. The conductive traces may be formed by sputtering, evaporation, electro-less plating, or electroplating. The conductive traces are embedded in the dielectric layers. The dielectric layers and the conductive traces may be alternatingly formed. The conductive traces may be formed in openings of the dielectric layers and on the dielectric layers. The conductive traces may be made of copper, aluminum, nickel, gold, silver, tin, a combination thereof, a composite structure of copper/nickel/gold, or other suitable conductive materials.

In the exemplary embodiment of FIG. 1F, the redistribution structure 192 includes four dielectric layers. However, the present disclosure is not limited thereto, as the number of the dielectric layers may be adjusted based on circuit design. A bottom dielectric layer of the redistribution structure 192 is adjacent to the second insulating encapsulant 154 and has openings filled with a bottom portion of the conductive traces that are directly in contact with the conductive pillars 170. As such, the first die 110 and the second die 120, are electrically connected to the redistribution structure 194.

In some embodiments, the bottom portion of the conductive traces may also be in direct contact with the rear surface 130b of the bridge die 130. A conductive trace of the conductive traces of the redistribution structure 192 may electrically connect with a conductive trace of the conductive traces of the semiconductor substrate 131 of the bridge die 130. In some embodiments, the semiconductor substrate 131 may include through silicon vias (TSV) to electrically connect a conductive trace of the redistribution structure 192 to one or more of the at least two dies, for instance the first die 110 or the second die 120, directly through the bridge die 130.

A top dielectric layer of the redistribution structure 192 is on the opposite side of the redistribution structure 192 to the bottom dielectric layer and exposes a top portion of the conductive traces. The top portion of the conductive traces may be formed as a plurality of under-ball metallization (UBM) pads. A plurality of conductive terminals 194 may be formed on the top portion of the conductive traces of the redistribution structure 192. The conductive terminals 194 may be formed by a ball placement process and/or a reflow process. The conductive terminals 194 may be conductive bumps such as solder balls. However, the present disclosure is not limited thereto. In some alternative embodiments, the conductive terminals 194 may take other possible forms and shapes based on design requirements. For example, the conductive terminals 194 may take the form of conductive pillars or conductive posts.

The redistribution structure 192 may be used to reroute electrical signals to/from the first die 110 and the second die 120, and may expand to a wider area than that of the at least two dies. Therefore, in some embodiments, the redistribution structure 192 may be referred to as a “fan-out redistribution structure”. As well as electrically connecting onward to other package structures or devices through the conductive terminals 192, the redistribution structure 192 may also electrically connect any conductive component of the package structure 100 to each other, if that conductive component is electrically connected to the redistribution structure 192. For example, the first die 110 and the second die 120 may also be electrically connected through the redistribution structure 192.

Referring to FIG. 1G, after forming the conductive terminals 194, the debonding layer 102 and the carrier 100 are removed from the first insulating encapsulant 150, the first die 110 and the second die 120 to expose the rear surface 110b of the first die 110 and the rear surface 120b of the second die 120. As mentioned above, the debonding layer 102 may be an LTHC layer. Upon exposure to a UV laser light, the debonding layer 102 and the carrier 100 may be peeled off and separated from the first insulating encapsulant 150, the first die 110 and the second die 120.

Referring to FIGS. 1A-1G, the carrier 100, the debonding layer 102, the first insulating encapsulant 150, the passivation layer 152, the second insulating encapsulant 154 and the redistribution structure 192 may extend horizontally in two dimensions along both directions in each of a length and a width beyond the area occupied by the first die 110 and the second die 120. The first die 110, the second die 120, the bridge die 130, the underfill 180, the plurality of conductive pillars 170 and the plurality of conductive terminals 194 may each be considered as a component of a package unit. A plurality of each component of the package unit may be included in the above described manufacturing method of a package structure as corresponds to each step, such that a plurality of package units is produced, and the package units are distributed apart from each other. For instance, the package units may be distributed in an array with constant spacing between the package units.

Referring to FIG. 1H, after removing the debonding layer 102 and the carrier 100, a singulation process is performed to obtain a plurality of package structures 100 each including one of the package units. The singulation process includes, for example, cutting with a rotating blade or a laser beam.

By using the bridge die 130 having the conductive bumps 132a and 132b, which can also be referred to as conductive microbumps, having a width and spacing of less than 2 micrometers to route signals between the first die 110 and the second die 120, a high density of interconnecting routes may be provided. The higher density of interconnecting routes allows for a high bandwidth transfer of signals between the first die 110 and the second die 120. The high bandwidth allows for faster communication between, for example, processor and memory dies, and thereby a faster operation of the package structure 100. Furthermore, the passivation layer 152, as well as isolating the first die 110 and the second die 120 from the bridge die 130, also provides a suitable surface to which the underfill 180 of the bridge die 130 can adhere to. The passivation layer 152 and underfill 180 of the bridge die 130 provide additional mechanical support to the interconnect assembly between the bridge die 130 and the at least two dies, that is the conductive bumps 132 of the bridge die 130 and the first conductive vias 160a. The passivation layer 152 also provides additional mechanical support to the interconnect assembly between the at least two dies and the redistribution structure 192, that is the conductive pillars 170 and the second conductive vias 160b. The additional mechanical support increases a reliability and durability of the package structure 100.

In some embodiments, having the bridge die 130 directly adjacent to the redistribution structure 192, allows for a direct electrical connection between the redistribution structure 192 and the bridge die 130 through the rear surface 130b of the bridge die 130, and also allows for an electrical connection from the redistribution structure 192 to the first die 110 or the second die 120 through, for example, a through silicon via (TSV) in the bridge die 130.

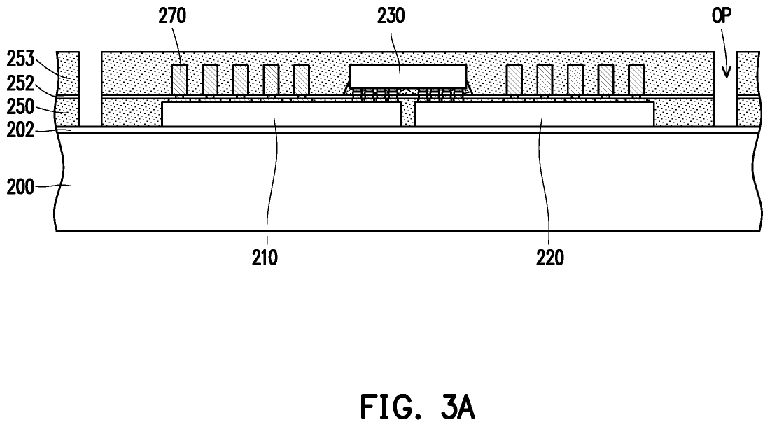

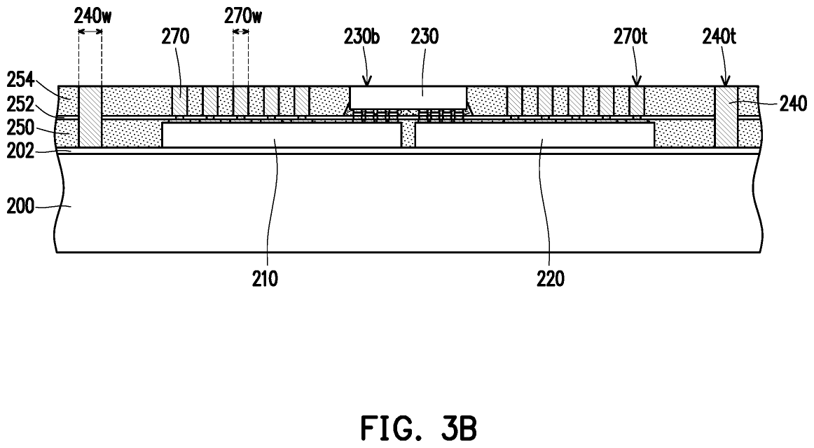

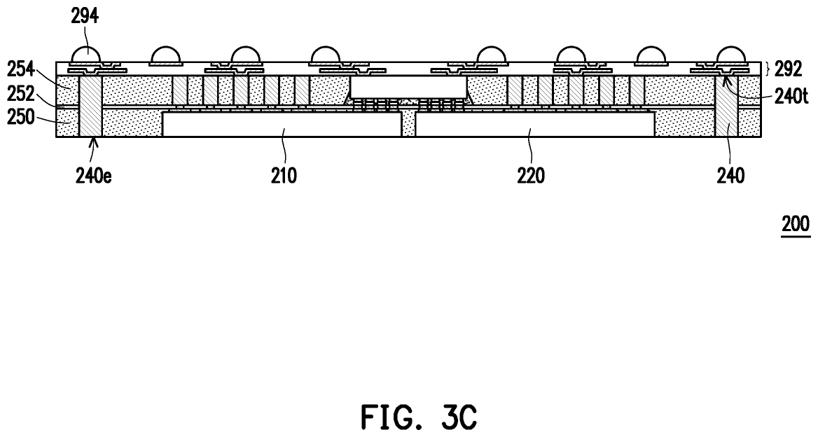

FIGS. 3A-3C are schematic cross-sectional views illustrating a package structure 200 according to some alternative embodiments of the disclosure. Referring to FIG. 3A, the package structure 200 in FIG. 3A is similar to the package structure 100 in FIG. 1E, so same or similar elements are denoted by the same or similar reference numerals and detailed descriptions thereof are not repeated here. The difference between the package structure 200 in FIG. 3A and the package structure 100 in FIG. 1E lies in that the package structure 200 has not yet had a thickness of an insulating material 253 reduced to form a second insulating encapsulant 254, and an opening OP is formed in the first insulating encapsulant 250, the passivation layer 252 and the insulating material 253 to expose the debonding layer 202 on the carrier 200. The opening OP may be formed at a periphery of the first die 210 and the second die 220. In some embodiments, the opening OP is formed by a laser drilling process.

Regarding FIG. 3B, a conductive connector 240 is formed to fill the opening OP. The conductive connector 240 may be formed by disposing a conductive material to fill the opening OP by plating, deposition or other suitable processes. The conductive connector 240 may be made of copper, aluminum, nickel, gold, a combination thereof, or other suitable conductive materials. A width 240w of the conductive connector 240 may be the same, greater than, or less than a width 270w of each of the conductive pillars 270.

A thickness of the insulating material 253 and the conductive connector 240 is reduced to expose the top surfaces 270t of the conductive pillars 270 and the rear surface 230b of the bridge die 230, thereby forming the second insulating encapsulant 254. In some embodiments, the top surfaces 270t, the rear surface 130b and a top surface 240t of the conductive connector 240 are substantially coplanar to each other. The second insulating encapsulant 254 may be formed and made of a material as described for the second insulating encapsulant 154 of the package structure 100.

Referring to FIG. 3C, a redistribution structure 292 is formed on the second insulating encapsulant 254. The redistribution structure 292 may be formed as described for the redistribution structure 192 in FIG. 1F. The difference between the redistribution structure 292 in FIG. 3C and the redistribution structure 192 in FIG. 1F lies in that the bottom portion of the conductive traces of the redistribution structure 292 may also be in direct contact with the top surface 240t of the conductive connector 240. As such, the redistribution structure 292 is electrically connected to the conductive connector 240.

After forming the redistribution structure 292, the manufacturing method of the package structure 200 follows the above described manufacturing method of the package structure 100 as shown in FIGS. 1F-1H to produce the package structure 200 shown in FIG. 3C. As illustrated in FIG. 3C, an exposed surface 240e opposite to the top surface 240t of the conductive connector 240 of the package structure 200 is exposed after removing the debonding layer 202 and the carrier 200.

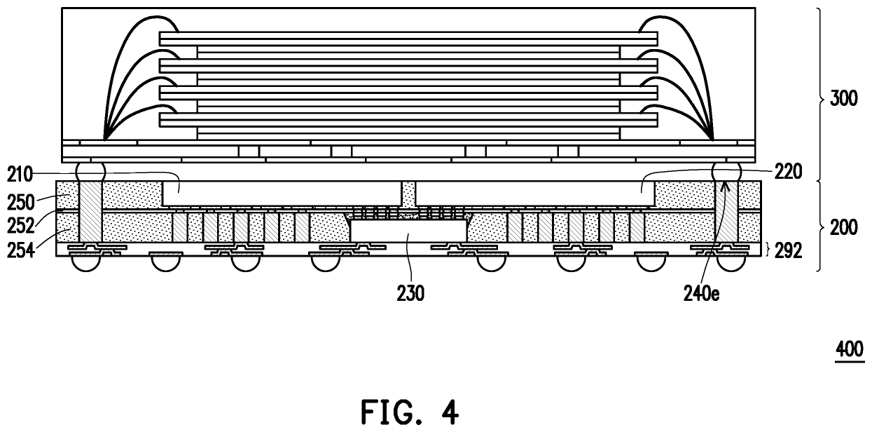

FIG. 4 is a schematic cross-sectional view illustrating an application of the package structure 200 according to an embodiment of the disclosure. A package structure 300 may be provided and then disposed on the conductive connector 240 opposite to the redistribution structure 292 to form a package-on-package (PoP) structure 400. In some embodiments, the package structure 300 may be electrically coupled to the first die 210, the second die 220 and the bridge die 230 at least through the conductive connector 240 and the redistribution structure 292. In some embodiments, the package structure 300 may be bonded to the package structure 200 with conductive joints (not shown) therebetween through flip chip bonding and/or surface-mount technology.

In some embodiments, the package structure 300 may include a chip stack, a redistribution layer electrically connected to the chip stack, an insulator disposed on the redistribution layer to encapsulate the chip stack, and external terminals electrically connected to the redistribution layer and opposite to the chip stack. The chip stack may be electrically connected to the redistribution layer through a plurality of conductive wires, but the present disclosure is not limited thereto. The insulator may encapsulate the conductive wires. The chip stack may comprise of a plurality of chips stacked on each other. The chips may include memory chips having non-volatile memory, such as NAND flash. However, the present disclosure is not limited thereto. In some alternative embodiments, the chips of the chip stack may include chips capable of performing other functions, such as logic functions, computing functions, or the like. A chip attachment layer may be disposed between two adjacent chips in the chip stack to enhance an adhesion between the two adjacent chips. It should be noted that the number of the chips shown to be stacked in the chip stack in FIG. 4 merely serves as an exemplary illustration and the present disclosure is not limited thereto.

After disposing the package structure 300 on the package structure 200, the external terminals of the package structure 300 may be positioned on the conductive connectors 240 of the package structure 200. A reflow process may be performed to bond the external terminals of the package structure 300 to the conductive connectors 240. Alternatively, other suitable methods may be used to attach the package structure 300 onto the package structure 200 to form the PoP structure 400.

As such, the package structure may include the conductive connectors, for example fanout through insulator vias (FO-TIV), to connect to another package structure stacked on top, thereby forming a PoP structure.

Based on the above, the bridge die of the package structure may be used to route signals between the at least two dies. The bridge die has conductive bumps, which can also be referred to as conductive microbumps, having a width and spacing of less than 2 micrometers that allow for a higher density of interconnecting routes between the at least two dies. The higher density of interconnecting routes allows for a high bandwidth transfer of signals between the at least two dies. The high bandwidth allows for faster communication between, for example, processor and memory dies, and thereby a faster operation of the package structure. Furthermore, the passivation layer, as well as isolating the at least two dies from the bridge die, also provides a suitable surface to which the underfill of the bridge die can adhere to. The passivation layer and underfill of the bridge die provide additional mechanical support to the interconnections within the package structure, thereby increasing the reliability and durability of the package structure.

Additionally, the bridge die may be disposed directly adjacent to the redistribution structure, allowing for a direct electrical connection between the redistribution structure and the bridge die through the rear surface of the bridge die. Such an arrangement also permits the addition of an electrical connection from the redistribution structure to one or more of the at least two dies through, for example, through silicon vias (TSV) in the bridge die.

The manufacturing method of the package structure does not require an expensive boring process in order to form the conductive pillars connecting the at least two dies to the redistribution structure, thereby reducing the time and cost of the manufacturing process of the package structure.

It will be apparent to those skilled in the art that various modifications and variations can be made to the embodiments and concepts disclosed herein without departing from the scope or spirit of the invention. In view of the foregoing, it is intended that the present disclosure cover modifications and variations of this invention provided they fall within the scope of the following claims and their equivalents.

What is claimed is:

1. A package structure, comprising:
a redistribution structure;
a bridge die disposed on the redistribution structure;
a plurality of conductive pillars disposed at a periphery of the bridge die and on the redistribution structure, wherein the conductive pillars are electrically connected to the redistribution structure;
at least two dies disposed on the bridge die and the conductive pillars opposite to the redistribution structure, wherein each of the at least two dies has an active surface and a lateral surface connected to the active surface and comprises a plurality of conductive pads disposed on the active surface and electrically connected to the bridge die and the conductive pillars; and
an insulating encapsulant disposed on the redistribution structure, encapsulating the bridge die and the conductive pillars, and covering the active surface and the lateral surface of each of the at least two dies.

2. The package structure according to claim 1, wherein the bridge die is in direct contact with the redistribution structure.

3. The package structure according to claim 1, further comprising a passivation layer disposed on the active surface of each of the at least two dies and comprising a plurality of openings exposing at least a portion of each of the conductive pads.

4. The package structure according to claim 3, wherein the openings comprise tapered openings tapered toward the conductive pads.

5. The package structure according to claim 3, further comprising
a plurality of conductive vias filling the openings of the passivation layer and comprising a plurality of first conductive vias electrically connecting each of the at least two dies to the bridge die and a plurality of second conductive vias electrically connecting each of the at least two dies to the conductive pillars, wherein a width of the first conductive vias is less than or equal to a width of the second conductive vias, and a spacing of the first conductive vias is shorter than a spacing of the second conductive vias.

6. The package structure according to claim 1, wherein
the bridge die has an active surface and comprises a plurality of first conductive bumps and a plurality of second conductive bumps disposed on the active surface of the bridge die, wherein
the first conductive bumps are electrically connected to a first die of the at least two dies,
the second conductive bumps are electrically connected to a second die of the at least two dies, and
a width of each of the first conductive bumps and the second conductive bumps, a spacing of the first conductive bumps and a spacing of the second conductive bumps are each less than 2 micrometers.

7. The package structure according to claim 3, further comprising an underfill disposed between the bridge die and the passivation layer.

8. The package structure according to claim 1, further comprising a plurality of conductive terminals disposed on the redistribution structure opposite to the bridge die and the conductive pillars, wherein the conductive terminals are electrically connected to the conductive pillars through the redistribution structure.

9. The package structure according to claim 1, further comprising:
a conductive connector disposed on the redistribution structure at a periphery of the conductive pillars and the at least two dies and electrically connected to the redistribution structure, wherein the insulating encapsulant laterally encapsulates the conductive connector.

10. The package structure according to claim 9, further comprising:
another package structure disposed on the insulating encapsulant opposite to the redistribution structure and electrically connected to the conductive connector.

11. A manufacturing method of a package structure, comprising:
providing a carrier;
disposing at least two dies on the carrier, wherein each of the at least two dies has an active surface and a rear surface opposite the active surface and comprises a plurality of conductive pads disposed on the active surface, and the rear surface faces the carrier;
disposing a bridge die and forming a plurality of conductive pillars on the at least two dies opposite to the carrier, wherein the bridge die has an active surface and a rear surface opposite the active surface of the bridge die, the bridge die is electrically connected to each of the at least two dies through the active surface of the bridge die, and the conductive pillars are electrically connected to each of the at least two dies;
forming an insulating encapsulant to encapsulate the at least two dies, the bridge die and the conductive pillars;
forming a redistribution structure on the insulating encapsulant opposite to the carrier, wherein the redistribution structure is electrically connected to the conductive pillars; and
removing the carrier from the insulating encapsulant and the at least two dies.

12. The method according to claim 11, wherein forming the insulating encapsulant comprises:
forming a first insulating encapsulant to encapsulate the at least two dies before disposing the bridge die and forming the conductive pillars; and
forming a second insulating encapsulant to encapsulate the bridge die and the conductive pillars, and
the method further comprises:
forming a passivation layer on the first insulating encapsulant opposite to the carrier; and
forming openings in the passivation layer before disposing the bridge die and forming the conductive pillars, wherein the openings expose at least a portion of each of the conductive pads.

13. The method according to claim 12, wherein the openings comprise tapered openings tapered toward the conductive pads.

14. The method according to claim 12, further comprising forming a plurality of conductive vias filling the openings of the passivation layer, wherein the conductive pillars are formed on some conductive vias of the conductive vias.

15. The method according to claim 11, wherein
the bridge die comprises a plurality of first conductive bumps and a plurality of second conductive bumps disposed on the active surface of the bridge die, wherein
a width of each of the first conductive bumps and the second conductive bumps, a spacing of the first conductive bumps and a spacing of the second conductive bumps are each less than 2 micrometers, and
disposing the bridge die comprises electrically connecting the first conductive bumps and the second conductive bumps to a first die and a second of the at least two dies respectively.

16. The method according to claim 12, further comprising forming an underfill between the passivation layer and the bridge die after disposing the bridge die.

17. The method according to claim 12, wherein
forming the first insulating encapsulant comprises:
forming a first insulating material over the at least two dies; and
removing a portion of the first insulating material to expose a top surface of the conductive pads, and
forming the second insulating encapsulant comprises:
forming a second insulating material over the bridge die and the conductive pillars; and
removing a portion of the insulating material to expose the rear surface of the bridge die and a top surface of the conductive pillars.

18. The method according to claim 11, further comprising forming a plurality of conductive terminals on the redistribution structure opposite to the bridge die and the conductive pillars, wherein the conductive terminals are electrically connected to the conductive pillars through the redistribution structure.

19. The method according to claim 11, further comprising
forming a conductive connector on the carrier at a periphery of the at least two dies before forming the redistribution structure, wherein the conductive connector is electrically connected to the redistribution structure and has an exposed surface opposite to the redistribution structure, and the exposed surface of the conductive connector is exposed after removing the carrier.

20. The method according to claim 11, wherein
the at least two dies, the bridge die and the plurality of conductive pillars are a package unit,
the package unit is plural,
the packet units are distributed apart from each other, and
the method further comprises performing a singulation process after removing the carrier.
